(19) United States
(12) Patent Application Publication
(10) Pub. No.: US 2025/0231535 A1
(43) Pub. Date: Jul. 17, 2025

(54) INFORMATION PROCESSING METHOD, COMPUTER PROGRAM, AND INFORMATION PROCESSING APPARATUS

(71) Applicant: Tokyo Electron Limited, Tokyo (JP)

(72) Inventors: Yukiya SAITOU, Sapporo (JP); Kei SANO, Austin, TX (US)

(73) Assignee: Tokyo Electron Limited, Tokyo (JP)

(21) Appl. No.: 19/170,089

(22) Filed: Apr. 4, 2025

Related U.S. Application Data
(63) Continuation of application No. PCT/JP2023/036834, filed on Oct. 11, 2023.

(30) Foreign Application Priority Data
Oct. 14, 2022 (JP) 2022-165617

(51) Int. Cl. G05B 13/04; G05B 13/02; H01L 21/66

(52) U.S. Cl. CPC G05B 13/041; G05B 13/0265; H01L 22/10

(57) ABSTRACT

An information processing apparatus acquires a sensor value of a target apparatus, inputs the acquired sensor value of the target apparatus to a sensor value conversion model, acquires the sensor value of the reference apparatus output by the sensor value conversion model, inputs the acquired sensor value of the reference apparatus together with a desired target value to a control input value determination model, acquires the control input value of the reference apparatus output by the control input value determination model, inputs the acquired control input value of the reference apparatus to a control input value conversion model, acquires the control input value of the target apparatus output by the control input value conversion model, and controls the target apparatus, based on the acquired control input value of the target apparatus.

### CROSS-REFERENCE TO RELATED APPLICATIONS

This application is a bypass continuation application of international application No. PCT/JP2023/036834 having an international filing date of Oct. 11, 2023, and designating the United States, the international application being based upon and claiming the benefit of priority from Japanese Patent Application No. 2022-165617, filed on Oct. 14, 2022, the entire contents of each are incorporated herein by reference.

### TECHNICAL FIELD

The present disclosure relates to an information processing method, a computer program, and an information processing apparatus.

### SUMMARY

The present disclosure provides an information processing method, a computer-readable medium storing a program, and an information processing apparatus which can be expected to control a target apparatus or the like by correcting an apparatus difference from a reference apparatus.

According to one or more embodiments, there is provided an information processing method causing an information processing apparatus to execute a process including acquiring a sensor value of a target apparatus, inputting the acquired sensor value of the target apparatus to a sensor value conversion model subjected to machine learning to receive the sensor value of the target apparatus as an input, and to output a sensor value of a reference apparatus, and acquiring the sensor value of the reference apparatus which is output by the sensor value conversion model, inputting the acquired sensor value of the reference apparatus together with a desired target value to a control input value determination model subjected to machine learning to receive the target value and the sensor value of the reference apparatus as inputs, and to output a control input value of the reference apparatus, and acquiring the control input value of the reference apparatus which is output by the control input value determination model, inputting the acquired control input value of the reference apparatus to a control input value conversion model subjected to machine learning to receive the control input value of the reference apparatus as an input, and to output a control input value of the target apparatus, and acquiring the control input value of the target apparatus which is output by the control input value conversion model, and controlling the target apparatus, based on the acquired control input value of the target apparatus.

According to the present disclosure, it can be expected to control a target apparatus or the like by correcting an apparatus difference from a reference apparatus.

### BRIEF DESCRIPTION OF DRAWINGS

FIG. 1 is a schematic diagram for explaining an example of an information processing system according to one or more embodiments.

FIG. 2 is a block diagram illustrating a configuration example of an information processing apparatus according to the present embodiment.

FIG. 3 is a schematic diagram illustrating a configuration example of a characteristic value estimation model.

FIG. 4 is a schematic diagram illustrating a configuration example of training data.

FIG. 5 is a schematic diagram illustrating a configuration example of a control input value determination model.

FIG. 6 is a schematic diagram illustrating a configuration example of a sensor value control input value relationship model.

FIG. 7 is a schematic diagram illustrating a configuration example of a sensor value conversion model.

FIG. 8 is a schematic diagram illustrating a configuration example of a control input value conversion model.

FIG. 9 is a schematic diagram for describing monitoring of a substrate processing apparatus which is performed by an information processing apparatus.

FIG. 10 is a schematic diagram for describing control of the substrate processing apparatus which is performed by the information processing apparatus.

FIG. 11 is a flowchart illustrating an example of a procedure of learning model generation processing performed by the information processing apparatus according to the present embodiment.

FIG. 12 is a flowchart illustrating an example of a procedure of the learning model generation processing performed by the information processing apparatus according to the present embodiment.

FIG. 13 is a flowchart illustrating an example of a procedure of monitoring and control processing of the substrate processing apparatus which are performed by the information processing apparatus according to the present embodiment.

FIG. 14 is a flowchart illustrating an example of a procedure of the monitoring and control processing of the substrate processing apparatus which are performed by the information processing apparatus according to the present embodiment.

FIG. 15 is a schematic diagram illustrating a configuration example of a control input value determination model according to a second embodiment.

FIG. 16 is a schematic diagram for describing control of a reference substrate processing apparatus which is performed by the information processing apparatus.

FIG. 17 is a schematic diagram for describing control of a target substrate processing apparatus which is performed by the information processing apparatus.

### DETAILED DESCRIPTION

Hereinafter, a specific example of an information processing system according to the embodiment of the present disclosure will be described with reference to the drawings. The present disclosure is not limited to these examples, and is defined by the claims, and is intended to include all modifications within the meaning and scope equivalent to the claims.

### <System Overview>

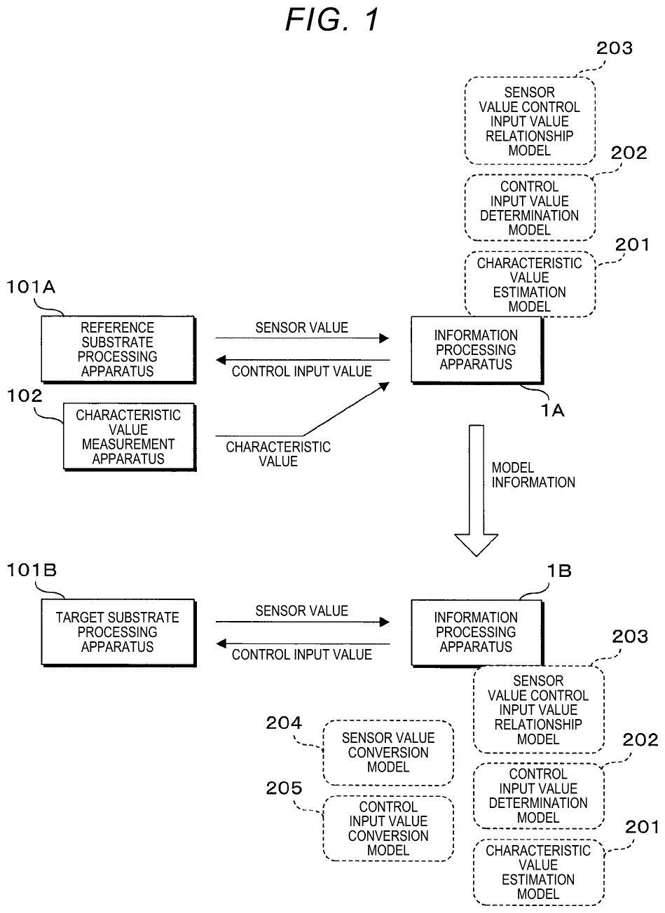

FIG. 1 is a schematic diagram for explaining an example of an information processing system according to one or more embodiments. The information processing system according to the present embodiment includes a substrate processing apparatus and an information processing apparatus. The substrate processing apparatus is an apparatus that performs various processing for substrate processing, for example, such as chemical vapor deposition (CVD), sputtering, or etching, and may be a semiconductor manufacturing apparatus, a flat panel display (FPD) manufacturing apparatus that manufactures a display panel, or the like. The information processing apparatus performs monitoring, controlling, or the like on an operation of the substrate processing apparatus. For example, the information processing apparatus acquires sensor value acquired from a plurality of sensors provided in the substrate processing apparatus, and determines a control input value for the substrate processing apparatus, based on the acquired sensor values. The information processing apparatus causes the substrate processing apparatus to perform substrate processing in such a manner that the information processing apparatus inputs the determined control input value to the substrate processing apparatus.

In FIG. 1, two of a reference substrate processing apparatus (reference apparatus) 101A and a target substrate processing apparatus (target apparatus) 101B are illustrated as substrate processing apparatuses, and two of an information processing apparatus 1A and an information processing apparatus 1B are illustrated as information processing apparatuses. The information processing apparatus 1A performs monitoring, controlling, or the like on the reference substrate processing apparatus 101A, and the information processing apparatus 1B performs monitoring, controlling, or the like on the target substrate processing apparatus 101B. For example, the reference substrate processing apparatus 101A is a substrate processing apparatus previously activated to be normally operated. In contrast, the target substrate processing apparatus 101B is basically the same apparatus as the reference substrate processing apparatus 101A. However, for example, the target substrate processing apparatus 101B is an apparatus newly produced, purchased, or the like to be newly added to a substrate processing factory or the like. The reference substrate processing apparatus 101A and the target substrate processing apparatus 101B are apparatuses basically having the same configuration. The information processing apparatuses 1A and 1B perform the same arithmetic processing, based on the acquired sensor values to determine a control input value, and input the determined control input value to the reference substrate processing apparatus 101A and the target substrate processing apparatus 101B. In this manner, it is expected to obtain the same processing result.

However, even when the apparatuses have the same configuration, for example, there may be an individual difference between sensors that output sensor values, an individual difference between processing mechanisms that perform substrate processing in accordance with the control input value, or the like. Therefore, even when the same control input value is input for the same sensor value, the same processing result may not be obtained in the reference substrate processing apparatus 101A and the target substrate processing apparatus 101B. The information processing system according to the present embodiment is a system that assists eliminating an apparatus difference between the reference substrate processing apparatus 101A and the target substrate processing apparatus 101B.

In the present example, the reference substrate processing apparatus 101A and the target substrate processing apparatus 101B are different apparatuses. However, the present disclosure is not limited thereto. For example, in some cases, when works of replacing a sensor, replacing a processing mechanism, maintenance of an apparatus, and the like are carried out for the substrate processing apparatus, operations or the like of the substrate processing apparatus may be changed before and after the works. In this case, the substrate processing apparatus before the work of the maintenance or the like can be regarded as the reference substrate processing apparatus 101A, and the substrate processing apparatus after the work can be regarded as the target substrate processing apparatus 101B. In this case, the information processing apparatuses 1A and 1B may be substantially the same apparatus. Even when the reference substrate processing apparatus 101A and the target substrate processing apparatus 101B are different apparatuses, when one information processing apparatus performs monitoring, controlling, or the like on a plurality of substrate processing apparatuses, the information processing apparatuses 1A and 1B may be the same apparatus.

The information processing apparatus 1A of the present embodiment uses a learning model subjected to machine learning in advance to perform monitoring, controlling, or the like on the reference substrate processing apparatus 101A. Therefore, the information processing apparatus 1A includes a characteristic value estimation model 201 and a control input value determination model 202. The characteristic value estimation model 201 is a learning model that estimates characteristics of a substrate processed by the reference substrate processing apparatus 101A, based on a sensor value acquired from a sensor of the reference substrate processing apparatus 101A and a control input value input to the reference substrate processing apparatus 101A. The information processing apparatus 1A can estimate a characteristic value of the substrate processed by the reference substrate processing apparatus 101A by using the characteristic value estimation model 201, and can perform processing, for example, such as displaying an estimation result to provide information, or stopping the apparatus when an abnormality is detected from the estimation result.

The control input value determination model 202 is a learning model that determines a control input value to be input to the reference substrate processing apparatus 101A, based on a target characteristic value (target value) of the substrate processed by the reference substrate processing apparatus 101A and a sensor value acquired from a sensor of the reference substrate processing apparatus 101A. The information processing apparatus 1A inputs the control input value determined by the control input value determination model 202 to the reference substrate processing apparatus 101A. In this manner, it can be expected to perform processing on the substrate which satisfies the target characteristic value.

The characteristic value is information acquired by measuring a substrate processed by the substrate processing apparatus with a characteristic value measurement apparatus 102. For example, when the substrate processing apparatus performs etching, a measurement value such as a depth of a hole formed through the etching may be the characteristic value. The characteristic value may be any value. A target characteristic value is a characteristic value required for the substrate processed by the substrate processing apparatus, and it is required that the characteristic value acquired by measuring the processed substrate with the characteristic value measurement apparatus 102 is the target characteristic value or a value close to the target characteristic value.

In order to generate the characteristic value estimation model 201 and the control input value determination model 202, the information processing apparatus 1A causes the reference substrate processing apparatus 101A to perform predetermined substrate processing. The information processing apparatus 1A collects data in which the sensor value acquired from the reference substrate processing apparatus 101A at this time, the control input value input to the reference substrate processing apparatus 101A, and the characteristic value acquired by measuring the processed substrates with characteristic value measurement apparatus 102 are associated. The information processing apparatus 1A can generate the characteristic value estimation model 201 and the control input value determination model 202 by performing machine learning processing by using data in which the sensor value, the control input value, and the characteristic value are associated.

The information processing apparatus 1A generates a sensor value control input value relationship model 203 when generating the characteristic value estimation model 201 and the control input value determination model 202. The sensor value control input value relationship model 203 is a learning model that learns a relationship between the plurality of sensor value acquired from the reference substrate processing apparatus 101A and the plurality of control input values input to the reference substrate processing apparatus 101A. That is, the sensor value control input value relationship model 203 is a learning model that estimates a value for complementing a missing value, for example, when any one of the plurality of sensor values and control input values is missing. The sensor value control input value relationship model 203 is not the learning model used when the information processing apparatus 1A performs monitoring, controlling, or the like on the reference substrate processing apparatus 101A, and is the learning model provided from the information processing apparatus 1A to the information processing apparatus 1B to eliminate an apparatus difference between the reference substrate processing apparatus 101A and the target substrate processing apparatus 101B as described above. The sensor value control input value relationship model 203 is generated through machine learning by using data of the sensor value and the control input value which are included in data used when the characteristic value estimation model 201 and the control input value determination model 202 are generated.

In the information processing system according to the present embodiment, the information processing apparatus 1B that performs monitoring, controlling, or the like on the target substrate processing apparatus 101B uses the learning models generated by the information processing apparatus 1A that performs monitoring, controlling, or the like on the reference substrate processing apparatus 101A. As described above, the characteristic value estimation model 201 and the control input value determination model 202 are generated, based on information acquired from the reference substrate processing apparatus 101A. The characteristic value estimation model 201 is the learning model that estimates the characteristic value from the sensor value and the control input value of the reference substrate processing apparatus 101A, and the control input value determination model 202 is the learning model that determines the control input value from the sensor value of the reference substrate processing apparatus 101A. Therefore, monitoring, control, or the like cannot be performed by using the learning models without any change in the target substrate processing apparatus 101B that is different from the reference substrate processing apparatus 101A, or sufficient accuracy and the like cannot be acquired even when monitoring, controlling, or the like is performed.

Therefore, in the information processing system according to the present embodiment, the information processing apparatus 1B can generate and use a sensor value conversion model 204 and a control input value conversion model 205 to eliminate an apparatus difference between the target substrate processing apparatus 101B and the reference substrate processing apparatus 101A, and can perform monitoring, controlling, or the like using the characteristic value estimation model 201 and the control input value determination model 202. The sensor value conversion model 204 is the learning model that converts the sensor value acquired from the target substrate processing apparatus 101B into the sensor value acquired from the reference substrate processing apparatus 101A. The control input value conversion model 205 is the learning model that converts the control input value input to the reference substrate processing apparatus 101A into the control input value input to the target substrate processing apparatus 101B.

In order to generate the sensor value conversion model 204 and the control input value conversion model 205, the information processing apparatus 1B causes the target substrate processing apparatus 101B to perform predetermined substrate processing. The information processing apparatus 1B collects data in which the sensor value acquired from the target substrate processing apparatus 101B at this time and the control input value input to the target substrate processing apparatus 101B are associated. The information processing apparatus 1B can generate the sensor value conversion model 204 and the control input value conversion model 205 by performing machine learning processing by using the data in which the sensor value and the control input value are associated and the sensor value control input value relationship model 203 provided from the information processing apparatus 1A.

In the present embodiment, the information processing apparatuses 1A and 1B perform processing for generating the learning models, that is, so-called machine learning processing. However, the present disclosure is not limited thereto. The machine learning processing may be performed by an apparatus other than the information processing apparatuses 1A and 1B, for example, a server device or the like having high arithmetic processing capability. In this case, the information processing apparatuses 1A and 1B collect information required for machine learning, transmit the collected information to a server device or the like, and acquire the learning model generated based on the information from the server device or the like.

### <Apparatus Configuration>

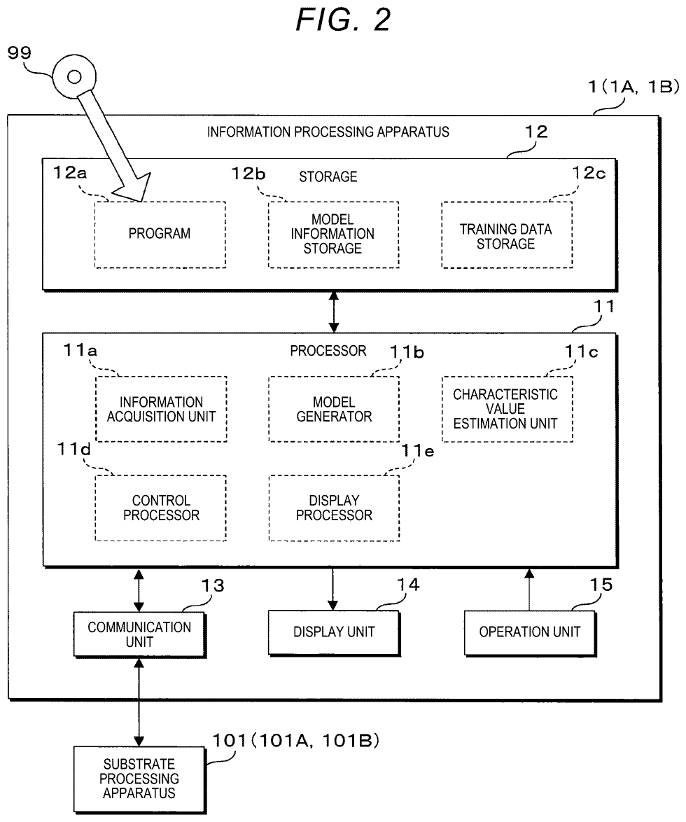

FIG. 2 is a block diagram illustrating a configuration example of the information processing apparatus according to the present embodiment. In the information processing system according to the present embodiment, each information processing apparatus may be either the information processing apparatus 1A that performs monitoring, controlling, or the like on the reference substrate processing apparatus 101A or the information processing apparatus 1B that performs monitoring, controlling, or the like on the target substrate processing apparatus 101B. Hereinafter, an apparatus capable of performing both the processing as the information processing apparatus 1A and the processing as the information processing apparatus 1B will be referred to as an information processing apparatus 1, and a configuration of the information processing apparatus 1 will be described. The reference substrate processing apparatus 101A and the target substrate processing apparatus 101B are apparatuses having substantially the same configurations, and when there is no need to distinguish the apparatuses from each other, in the following description, the reference substrate processing apparatus 101A and the target substrate processing apparatus 101B will be simply referred to as a substrate processing apparatus 101.

The information processing apparatus 1 according to the present embodiment includes a processor 11, a storage 12, a communication unit 13, a display unit 14, an operation unit 15, and the like. In the present embodiment, an example will be described in which a process is performed by one information processing apparatus 1. Meanwhile, the process of the information processing apparatus 1 may be distributed and performed by a plurality of apparatuses.

The processor 11 is configured by using an arithmetic processing apparatus such as a central processing unit (CPU), a micro-processing unit (MPU), a graphics processing unit (GPU), or a quantum processor, a read only memory (ROM), a random access memory (RAM), and the like. The processor 11 reads and executes a program 12a stored in the storage 12, thereby performing various processing such as processing for monitoring, controlling, or the like on the substrate processing apparatus 101, and processing for generating the learning models required for the processing. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

The storage 12 is configured by using, for example, a large-capacity storage apparatus such as a hard disk. The storage 12 stores various types of programs to be executed by the processor 11 and various types of data necessary for the process of the processor 11. In the present embodiment, the storage 12 stores the program 12a to be executed by the processor 11. The storage 12 is provided with a model information storage 12b that stores information on the plurality of learning models described above, and a training data storage 12c that stores the training data used for machine learning to generate the learning models.

In the present embodiment, the program (computer program, program product) 12a is provided in a form recorded on a recording medium 99 such as a memory card or an optical disc. The information processing apparatus 1 reads the program 12a from the recording medium 99, and stores the program 12a in the storage 12. However, for example, the program 12a may be written into the storage 12 during a manufacturing stage of the information processing apparatus 1. For example, as the program 12a, the information processing apparatus 1 may acquire those which are distributed by a remote server device or the like through communication. For example, the program 12a may be written into the storage 12 of the information processing apparatus 1 after a writing apparatus reads data recorded in the recording medium 99. The program 12a may be provided in the form of distribution through a network, or may be provided in the form recorded in the recording medium 99.

The model information storage 12b of the storage 12 stores information on the learning models such as the characteristic value estimation model 201, the control input value determination model 202, the sensor value control input value relationship model 203, the sensor value conversion model 204, and the control input value conversion model 205 which are described above. For example, the information on the learning model may include configuration information indicating whether the learning model has any configuration, and information such as values of internal parameters of the learning model. In a case of the information processing apparatus 1A that performs monitoring, controlling, or the like on the reference substrate processing apparatus 101A, the model information storage 12b stores at least information on the characteristic value estimation model 201, the control input value determination model 202, and the sensor value control input value relationship model 203. In a case of the information processing apparatus 1B that performs monitoring, controlling, or the like on the target substrate processing apparatus 101B, information on the characteristic value estimation model 201, the control input value determination model 202, the sensor value control input value relationship model 203, the sensor value conversion model 204, and the control input value conversion model 205 is stored.

The training data storage 12c of the storage 12 stores training data required for machine learning processing for generating the above-described learning model. In a case of the information processing apparatus 1A that performs monitoring, controlling, or the like on the reference substrate processing apparatus 101A, data in which the sensor value acquired by the sensor in the reference substrate processing apparatus 101A, the control input value input to the reference substrate processing apparatus 101A, and the characteristic value measured by the characteristic value measurement apparatus 102 on the substrate processed by the reference substrate processing apparatus 101A are associated is stored as the training data in the training data storage 12c. In a case of the information processing apparatus 1B that performs monitoring, controlling, or the like on the target substrate processing apparatus 101B, data in which the sensor value acquired by the sensor in the target substrate processing apparatus 101B and the control input value input to the target substrate processing apparatus 101B are associated is stored as the training data in the training data storage 12c.

The communication unit 13 communicates with various apparatuses via a wired or wireless network N including a local area network (LAN), the Internet, a cellular phone communication network, or the like. For example, the communication unit 13 may be configured by using an IC of a transceiver. In the present embodiment, the communication unit 13 communicates with the substrate processing apparatus 101, the characteristic value measurement apparatus 102, and the other information processing apparatuses 1, and the like. The communication unit 13 transmits data supplied from the processor 11 to another apparatus, and supplies data received from another apparatus to the processor 11.

The display unit 14 is configured by using a liquid crystal display or the like, and displays various images, characters, and the like based on the process of the processor 11. The display unit 14 displays various information on an operation of the substrate processing apparatus 101, for example, information on the characteristic value estimated by the characteristic value estimation model 201. The operation unit 15 receives a user operation and notifies the processor 11 of the received operation. For example, the operation unit 15 receives the user operation by an input device such as a mechanical button or a touch panel provided on a surface of the display unit 14. For example, the operation unit 15 may be an input device such as a mouse and a keyboard, and these input devices may be configured to be detachable from the information processing apparatus 1.

The storage 12 may be an external storage device connected to the information processing apparatus 1. The information processing apparatus 1 may be a multi-computer including a plurality of computers, or may be a virtual machine virtually constructed by software. In addition, the information processing apparatus 1 is not limited to the configuration described above, and does not need to include the display unit 14, the operation unit 15, and the like, for example.

In the information processing apparatus 1 of the present embodiment, the processor 11 reads and executes the program 12a stored in the storage 12. In this manner, an information acquisition unit 11a, a model generator 11b, a characteristic value estimation unit 11c, a control processor 11d, a display processor 11e, and the like are realized as software-like functional units in the processor 11.

The information acquisition unit 11a communicates with the substrate processing apparatus 101 through the communication unit 13, thereby acquiring various sensor values detected by a plurality of sensors provided in the substrate processing apparatus 101, for example, values such as a temperature or a pressure. The information acquisition unit 11a acquires a plurality of control input values input to the substrate processing apparatus 101 for the acquired sensor values, for example, values such as a driving amount of an actuator or a voltage value to be applied. In a case of the information processing apparatus 1A that performs monitoring, controlling, or the like on the reference substrate processing apparatus 101A, the information acquisition unit 11a communicates with the characteristic value measurement apparatus 102 via the communication unit 13, thereby acquiring the characteristic value of the substrate measured by the characteristic value measurement apparatus 102. The information acquisition unit 11a associates the acquired information with each other as the training data, and stores the training data in the training data storage 12c.

The model generator 11b performs machine learning processing using the training data stored in the training data storage 12c, thereby generating each of the learning models described above. In the present embodiment, as each of the learning models, for example, a learning model having various configurations such as a neural network, a support vector machine (SVM), and a random forest may be adopted. Each of the learning models may handle time series information, and in this case, a learning model having a configuration such as a recurrent neural network (RNN) or a long short term memory (LSTM) may be adopted. Since a structure of the learning models and a method for generating the learning model through the machine learning are existing techniques, detailed description thereof will be omitted in the present embodiment. In a case of the information processing apparatus 1A that performs monitoring, controlling, or the like on the reference substrate processing apparatus 101A, the model generator 11b generates the characteristic value estimation model 201, the control input value determination model 202, and the sensor value control input value relationship model 203. In a case of the information processing apparatus 1B that performs monitoring, controlling, or the like on the target substrate processing apparatus 101B, the model generator 11b generates the sensor value conversion model 204 and the control input value conversion model 205.

While the substrate processing apparatus 101 performs substrate processing, the characteristic value estimation unit 11c performs processing for estimating the characteristic value of the substrate processed by the substrate processing apparatus 101 by using the characteristic value estimation model 201 and the control input value determination model 202 which are stored in the model information storage 12b. The characteristic value estimation unit 11c inputs the sensor value and the target characteristic value which are acquired from the substrate processing apparatus 101 to the control input value determination model 202, acquires the control input value output by the control input value determination model 202, inputs the sensor value and the control input value to the characteristic value estimation model 201, and acquires the characteristic value output by the characteristic value estimation model 201. For example, the characteristic value estimation unit 11c can compare the characteristic value acquired from the characteristic value estimation model 201 with a predetermined threshold value, and can determine whether the substrate processed by the substrate processing apparatus 101 satisfies a target characteristic value.

However, in a case of the information processing apparatus 1B that performs monitoring, controlling, or the like on the target substrate processing apparatus 101B, the sensor value acquired from the target substrate processing apparatus 101B cannot be directly input to the characteristic value estimation model 201 and the control input value determination model 202. The characteristic value estimation unit 11c of the information processing apparatus 1B inputs the sensor value acquired from the target substrate processing apparatus 101B to the sensor value conversion model 204, acquires the sensor value of the reference substrate processing apparatus 101A output by the sensor value conversion model 204, and inputs the sensor value to the characteristic value estimation model 201 and the control input value determination model 202.

The control processor 11d determines the control input value by using the control input value determination model 202 stored in the model information storage 12b, based on the sensor value acquired from the substrate processing apparatus 101, and controls substrate processing performed by the substrate processing apparatus 101 by inputting the determined control input value to the substrate processing apparatus 101. The control processor 11d inputs the sensor value acquired from the substrate processing apparatus 101 and the target characteristic value of the substrate processed by the substrate processing apparatus 101 to the control input value determination model 202, and acquires the control input value output by the control input value determination model 202. The control processor 11d inputs the acquired control input value to the substrate processing apparatus 101, and causes the substrate processing apparatus 101 to perform processing for the substrate that satisfies the target characteristic value.

However, in a case of the information processing apparatus 1B that performs monitoring, controlling, or the like on the target substrate processing apparatus 101B, the sensor value acquired from the target substrate processing apparatus 101B cannot be directly input to the control input value determination model 202. The control processor 11d of the information processing apparatus 1B inputs the sensor value acquired from target substrate processing apparatus 101B to the sensor value conversion model 204, acquires the sensor value of the reference substrate processing apparatus 101A which is output by sensor value conversion model 204, and inputs the sensor value to the control input value determination model 202. Similarly, in a case of the information processing apparatus 1B that performs monitoring, controlling, or the like on the target substrate processing apparatus 101B, the control input value output by the control input value determination model 202 cannot be directly input to the target substrate processing apparatus 101B. The control processor 11d of the information processing apparatus 1B inputs the control input value acquired from the control input value determination model 202 to the control input value conversion model 205, acquires the control input value output by the control input value conversion model 205, and inputs the control input value to the target substrate processing apparatus 101B.

The display processor 11e performs processing for displaying various types of information on the display unit 14. For example, the display processor 11e displays an estimation result of the characteristic value which is acquired by the characteristic value estimation unit 11c. For example, when it is determined that the estimated characteristic value of the substrate processed by the substrate processing apparatus 101 does not satisfy the target characteristic value, the display processor 11e can display a warning message or the like notifying the determination result on the display unit 14. The display processor 11e may display various types of information other than the estimation result of the characteristic value, for example, information such as a progress of substrate processing performed by the substrate processing apparatus 101 or a graph indicating a change in the sensor value acquired from the substrate processing apparatus 101.

### <Configuration and Generation Method of Learning Model>

Five learning models generated and used in the information system according to the present embodiment will be described. In the examples described below, five sensor values are acquired from the substrate processing apparatus 101, three control input values are input to the substrate processing apparatus 101, and one characteristic value is measured by the characteristic value measurement apparatus 102. The reason is for the purpose of simplifying the description, and the number of the sensor values, the control input values, and the characteristic values is not limited to the number described above, and any number of the values may be used.

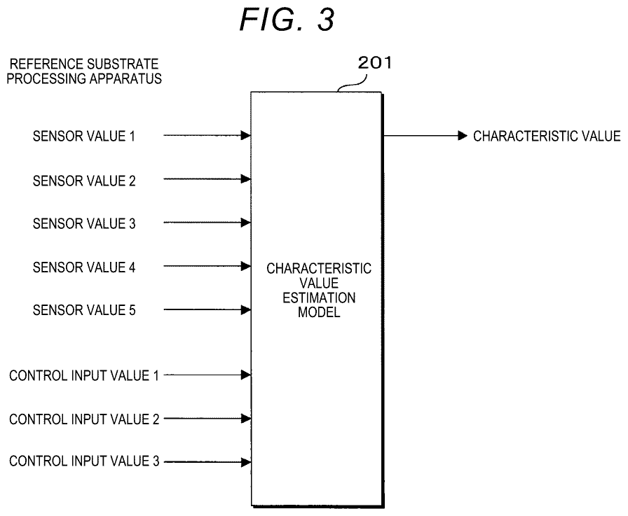

FIG. 3 is a schematic diagram illustrating a configuration example of the characteristic value estimation model 201. The characteristic value estimation model 201 according to the present embodiment receives the five sensor values 1 to 5 on the reference substrate processing apparatus 101A and the three control input values 1 to 3 input to the reference substrate processing apparatus 101A as inputs, and outputs an estimation result of the characteristic value of the substrate processed by the reference substrate processing apparatus 101A. Based on the characteristic value output by the characteristic value estimation model 201, the information processing apparatus 1 can determine whether the characteristic value of the substrate processed by the substrate processing apparatus 101 satisfies a target characteristic value.

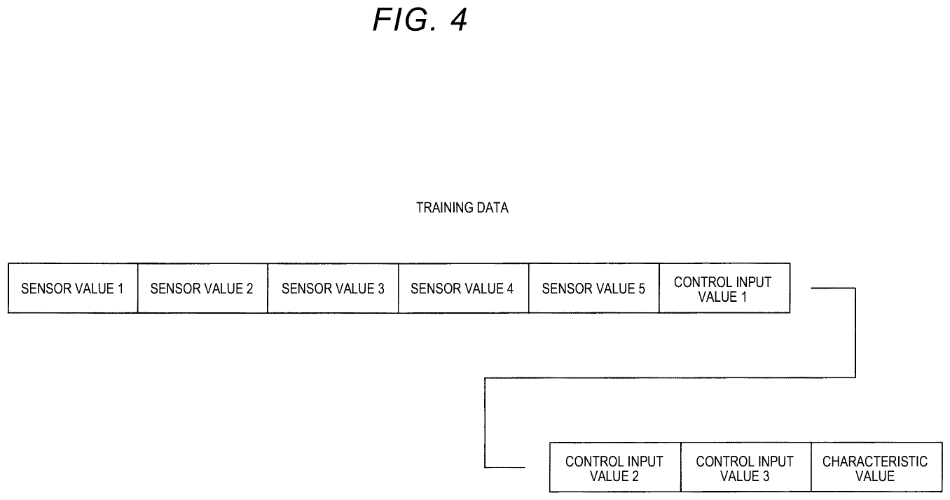

The characteristic value estimation model 201 is generated by the information processing apparatus 1A that performs monitoring, controlling, or the like on the reference substrate processing apparatus 101A. The information processing apparatus 1A collects training data in advance to perform machine learning processing for generating the characteristic value estimation model 201. FIG. 4 is a schematic diagram illustrating a configuration example of the training data. The information processing apparatus 1A performs substrate processing in the reference substrate processing apparatus 101A, acquires sensor values 1 to 5 from the sensors of the reference substrate processing apparatus 101A at this time, acquires the control input values 1 to 3 input to the reference substrate processing apparatus 101A in accordance with the sensor values 1 to 5, and stores the acquired sensor values 1 to 5 and the acquired control input values 1 to 3 in association with each other. The information processing apparatus 1A may repeatedly acquire the sensor values 1 to 5 and the control input values 1 to 3 at a predetermined interval, and may store time series information of the sensor values 1 to 5 and the control input values 1 to 3 in the training data storage 12c.

After the processing of the reference substrate processing apparatus 101A is completed, the information processing apparatus 1A acquires the characteristic value acquired by measuring the processed substrate by the characteristic value measurement apparatus 102, and stores the acquired characteristic values in association with the sensor values 1 to 5 and the control input values 1 to 3 which are acquired during the processing of the substrate. When the information processing apparatus 1A repeatedly acquires the sensor values 1 to 5 and the control input values 1 to 3, the common characteristic values may be stored in association with a plurality of sets of the sensor values 1 to 5 and the control input values 1 to 3.

For example, the information processing apparatus 1A performs so-called supervised machine learning processing on the learning model having a configuration of eight inputs and one output, in which input information (explanatory variable) is set for the sensor values 1 to 5 and the control input values 1 to 3 which are included in the training data stored in the training data storage 12c, and output information (response variable, correct value) is set for the characteristic value. In this manner, the information processing apparatus 1A can determine internal parameters of the learning model, and can generate the characteristic value estimation model 201.

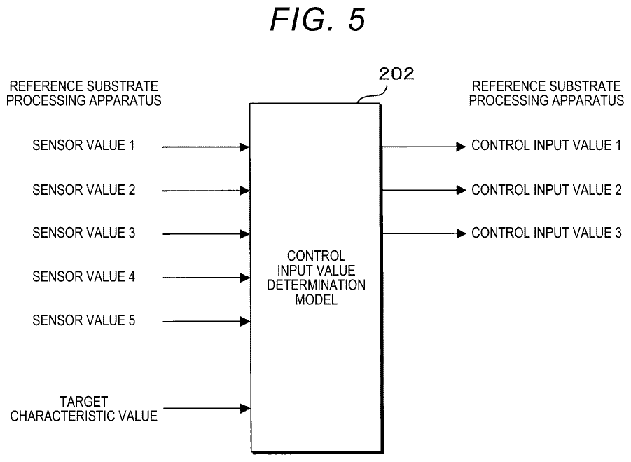

FIG. 5 is a schematic diagram illustrating a configuration example of the control input value determination model 202. The control input value determination model 202 according to the present embodiment receives the five sensor values 1 to 5 on the reference substrate processing apparatus 101A and the target characteristic values relating to the substrate processed by the reference substrate processing apparatus 101A as inputs, and outputs the three control input values 1 to 3 to be input to the reference substrate processing apparatus 101A. The target characteristic value is determined in advance before the substrate processing is started by the substrate processing apparatus 101, and is stored in the storage 12 of the information processing apparatus 1 or the like.

The control input value determination model 202 is generated by the information processing apparatus 1A that performs monitoring, controlling, or the like on the reference substrate processing apparatus 101A. The information processing apparatus 1A can generate the control input value determination model 202 by using the same data as the training data used to generate the characteristic value estimation model 201. For example, the information processing apparatus 1A performs so-called supervised machine learning processing on the learning model having a configuration of six inputs and three outputs, in which input information (explanatory variable) is set for the sensor values 1 to 5 and the characteristic value which are included in the training data stored in the training data storage 12c, and output information (response variable, correct value) is set for the control input values 1 to 3. In this manner, the information processing apparatus 1A can determine internal parameters of the learning model, and can generate the control input value determination model 202.

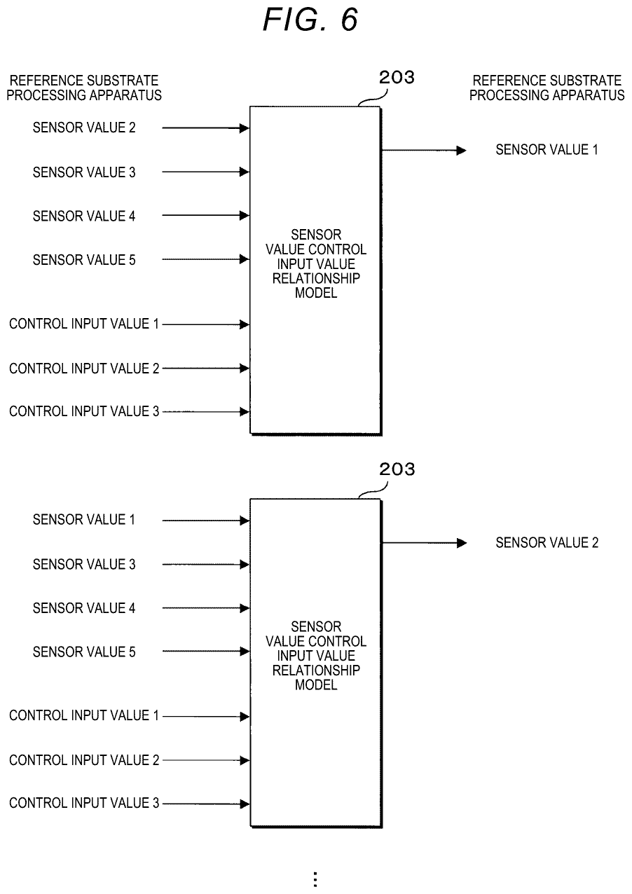

FIG. 6 is a schematic diagram illustrating a configuration example of the sensor value control input value relationship model 203. In the information processing system according to the present embodiment, the sensor value control input value relationship model 203 is generated to have the total number (5+3=8 in the present example) of sensor values and control input values. FIG. 6 illustrates two configuration examples of the eight sensor value control input value relationship models 203. The remaining six are omitted from the drawing.

The sensor value control input value relationship model 203 of the present embodiment is the learning model that estimates (complements) one value in the sensor values 1 to 5 and the control input values 1 to 3 from the other seven values. The sensor value control input value relationship model 203 illustrated at a first position in FIG. 6 receives the sensor values 2 to 5 and the control input values 1 to 3 relating to the reference substrate processing apparatus 101A as inputs, and outputs the sensor value 1 relating to the reference substrate processing apparatus 101A. The sensor value control input value relationship model 203 illustrated at a second position in FIG. 6 receives the sensor values 1 and 3 to 5 and the control input values 1 to 3 relating to the reference substrate processing apparatus 101A as inputs, and outputs the sensor value 2 relating to the reference substrate processing apparatus 101A. Similarly, the sensor value control input value relationship model 203 that outputs the sensor value 3, the sensor value control input value relationship model 203 that outputs the sensor value 4, . . . , and the sensor value control input value relationship model 203 that outputs control input value 3 exist.

Each of the sensor value control input value relationship models 203 is generated by the information processing apparatus 1A that performs monitoring, controlling, or the like on the reference substrate processing apparatus 101A. The information processing apparatus 1A can generate the sensor value control input value relationship model 203 by using the same data as the training data used to generate the characteristic value estimation model 201. For example, the information processing apparatus 1A performs so-called supervised machine learning processing on the learning model having a configuration of seven inputs and one output, in which output information (response variable, correct value) is set for any one of the sensor values 1 to 5 and the control input values 1 to 3 which are included in the training data stored in the training data storage 12c, and input information (explanatory variable) is set for the remaining seven. In this manner, the information processing apparatus 1A can determine the internal parameters of the learning model, and can generate the sensor value control input value relationship model 203. The information processing apparatus 1A replaces a correspondence between input information and output information to perform similar machine learning processing, thereby generating eight types of sensor value control input value relationship models 203.

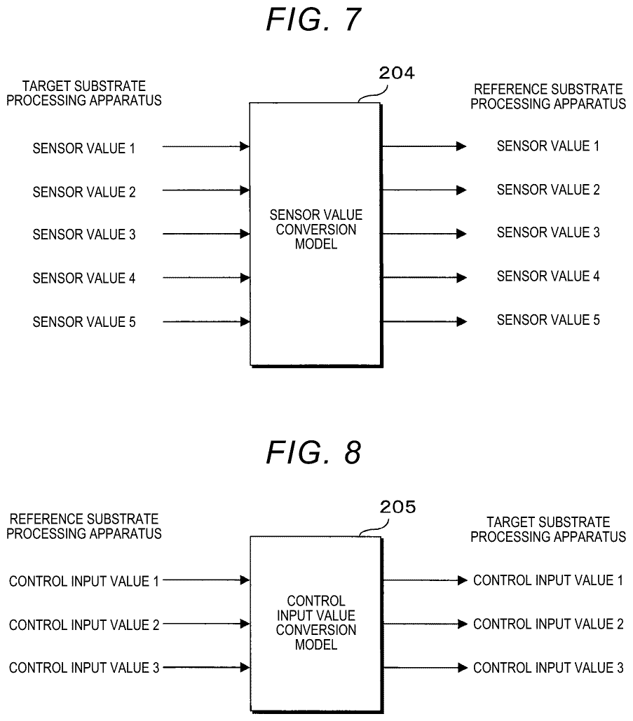

FIG. 7 is a schematic diagram illustrating a configuration example of the sensor value conversion model 204. The sensor value conversion model 204 according to the present embodiment receives the sensor values 1 to 5 relating to the target substrate processing apparatus 101B as inputs, and outputs the sensor values 1 to 5 relating to the reference substrate processing apparatus 101A. FIG. 8 is a schematic diagram illustrating a configuration example of the control input value conversion model 205. The control input value conversion model 205 according to the present embodiment receives the control input values 1 to 3 relating to the reference substrate processing apparatus 101A as inputs, and outputs the control input values 1 to 3 relating to the target substrate processing apparatus 101B.

The sensor value conversion model 204 and the control input value conversion model 205 according to the present embodiment are generated by the information processing apparatus 1B that performs monitoring, controlling, or the like on the target substrate processing apparatus 101B. The information processing apparatus 1B collects the training data in advance to perform the machine learning processing for generating the sensor value conversion model 204 and the control input value conversion model 205. The information processing apparatus 1B performs predetermined substrate processing, for example, substrate processing such as a trial run for which settings or procedures are defined for data collection purposes, on the target substrate processing apparatus 101B. The information processing apparatus 1B acquires the sensor values 1 to 5 from the sensors of the target substrate processing apparatus 101B at this time, and acquires the control input values 1 to 3 input to the target substrate processing apparatus 101B in accordance with the sensor values 1 to 5. The information processing apparatus 1B stores the acquired sensor values 1 to 5 and the acquired control input values 1 to 3 as the training data in association with each other. The training data used to generate the sensor value conversion model 204 and the control input value conversion model 205 may include the sensor values 1 to 5 and the control input values 1 to 3 which are described above, and does not need to include the characteristic value. Therefore, it is not necessary to measure the characteristic value by using the characteristic value measurement apparatus 102 for the substrate processed by the target substrate processing apparatus 101B. The information processing apparatus 1B generates the sensor value conversion model 204 and the control input value conversion model 205 by using the training data in which the collected sensor values 1 to 5 and the collected control input values 1 to 3 are associated, and the sensor value control input value relationship model 203 generated by the information processing apparatus 1A.

The information processing apparatus 1A reads the sensor values 1 to 5 and the control input values 1 to 3 which are included in the training data collected from the target substrate processing apparatus 101B. For example, the information processing apparatus 1A inputs the sensor values 2 to 5 and the control input values 1 to 3 to the sensor value control input value relationship model 203 configured as illustrated in an upper stage in FIG. 6, and acquires the sensor value 1 output by the sensor value control input value relationship model 203. The information processing apparatus 1A uses the sensor value 1 output by the sensor value control input value relationship model 203 as the sensor value 1 of the reference substrate processing apparatus 101A which corresponds to the sensor value 1 of the target substrate processing apparatus 101B. Similarly, the information processing apparatus 1B acquires the sensor values 2 to 5 and the control input values 1 to 3 of the reference substrate processing apparatus 101A which correspond to the sensor values 2 to 5 and the control input values 1 to 3 of the target substrate processing apparatus 101B, from the sensor value control input value relationship model 203. In this manner, the information processing apparatus 1A can acquire the sensor values 1 to 5 and the control input values 1 to 3 of the reference substrate processing apparatus 101A which respectively correspond to the sensor values 1 to 5 and the control input values 1 to 3 of the target substrate processing apparatus 101B.

For example, the information processing apparatus 1A performs so-called supervised machine learning processing on the learning model having a configuration of five inputs and five outputs, in which input information (explanatory variable) is set for the sensor values 1 to 5 of the target substrate processing apparatus 101B which are included in the training data, and output information (response variable, correct value) is set for the sensor values 1 to 5 of the reference substrate processing apparatus 101A which are acquired from the sensor value control input value relationship model 203. In this manner, the information processing apparatus 1A determines the internal parameters of the learning model, and generates the sensor value conversion model 204. For example, the information processing apparatus 1A performs so-called supervised machine learning processing on the learning model having a configuration of three inputs and three outputs, in which input information (explanatory variable) is set for the control input values 1 to 3 of the target substrate processing apparatus 101B which are included in the training data, and output information (response variable, correct value) is set for the control input values 1 to 3 of the reference substrate processing apparatus 101A which are acquired from the sensor value control input value relationship model 203. In this manner, the information processing apparatus 1A determines the internal parameters of the learning model, and generates the control input value conversion model 205.

### <Use of Learning Model>

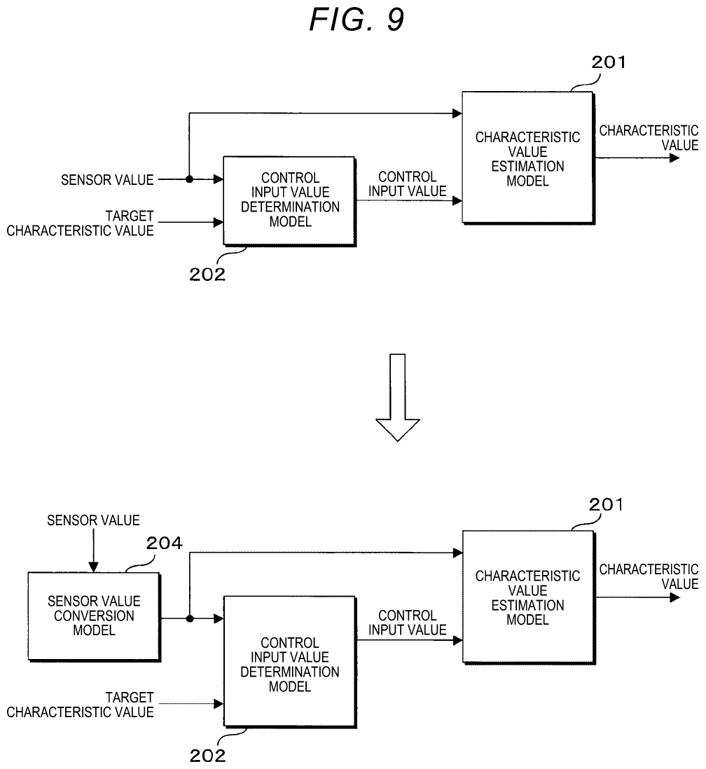

The information processing apparatus 1 performs monitoring, controlling, or the like on the substrate processing apparatus 101 by using the characteristic value estimation model 201, the control input value determination model 202, the sensor value conversion model 204, and the control input value conversion model 205 which are generated by the method described above. FIG. 9 is a schematic diagram for describing the monitoring of the substrate processing apparatus 101 which is performed by the information processing apparatus 1. An upper stage in FIG. 9 illustrates a case where the information processing apparatus 1A monitors the reference substrate processing apparatus 101A, and a lower stage in FIG. 9 illustrates a case where the information processing apparatus 1B monitors the target substrate processing apparatus 101B.

As illustrated in the upper stage in FIG. 9, the information processing apparatus 1A inputs the sensor value acquired from the reference substrate processing apparatus 101A and the target characteristic values of substrates to be processed to the control input value determination model 202, and acquires the control input value output by the control input value determination model 202. The information processing apparatus 1A inputs the sensor value acquired from the reference substrate processing apparatus 101A and the control input value acquired from the control input value determination model 202 to the characteristic value estimation model 201, and acquires the characteristic value output by the characteristic value estimation model 201. For example, the information processing apparatus 1A determines whether the characteristic value estimated by the characteristic value estimation model 201 falls within a predetermined range, and notifies occurrence of an abnormality when the characteristic value falls outside the predetermined range.

As illustrated in the lower stage in FIG. 9, the information processing apparatus 1B inputs the sensor value acquired from the target substrate processing apparatus 101B to the sensor value conversion model 204, and acquires the sensor value output by the sensor value conversion model 204, that is, the sensor value converted into the sensor value of the reference substrate processing apparatus 101A. The information processing apparatus 1B inputs the sensor value acquired from the sensor value conversion model 204 and the target characteristic value of the substrate to be processed to the control input value determination model 202, and acquires the control input value output by the control input value determination model 202. The information processing apparatus 1B inputs sensor value acquired from the sensor value conversion model 204 and control input value acquired from the control input value determination model 202 to the characteristic value estimation model 201, and acquires the characteristic value output by the characteristic value estimation model 201. For example, the information processing apparatus 1B determines whether the characteristic value estimated by the characteristic value estimation model 201 falls within a predetermined range, and notifies the occurrence of the abnormality when the characteristic value falls outside the predetermined range.

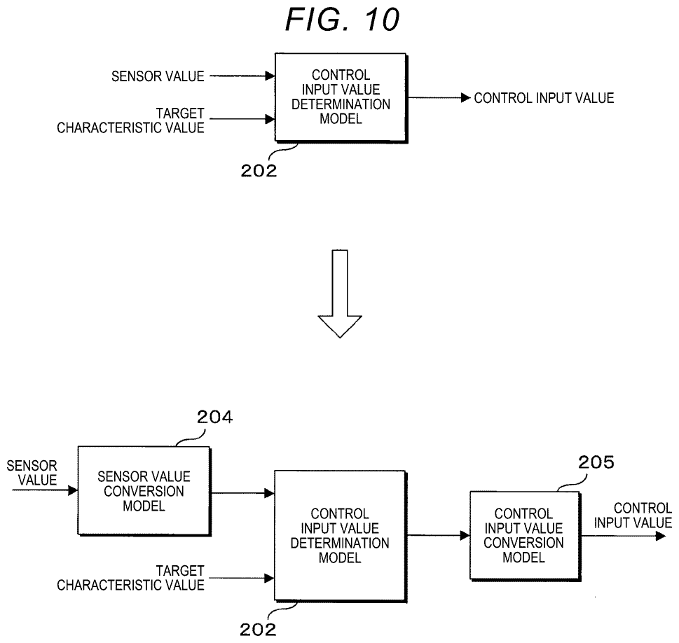

FIG. 10 is a schematic diagram for describing the control of the substrate processing apparatus 101 which is performed by the information processing apparatus 1. The upper stage in FIG. 10 illustrates a case where the information processing apparatus 1A controls the reference substrate processing apparatus 101A, and the lower stage in FIG. 10 illustrates a case where the information processing apparatus 1B controls the target substrate processing apparatus 101B.

As illustrated in the upper stage in FIG. 10, the information processing apparatus 1A inputs the sensor value acquired from the reference substrate processing apparatus 101A and the target characteristic value of the substrate to be processed to the control input value determination model 202, and acquires the control input value output by the control input value determination model 202. The information processing apparatus 1A inputs the control input value acquired from the control input value determination model 202 to the reference substrate processing apparatus 101A, thereby causing the reference substrate processing apparatus 101A to perform substrate processing corresponding to the target characteristic value.

As illustrated in the lower stage in FIG. 10, the information processing apparatus 1B inputs the sensor value acquired from the target substrate processing apparatus 101B to the sensor value conversion model 204, and acquires the sensor value output by the sensor value conversion model 204, that is, the sensor value converted into the sensor value of the reference substrate processing apparatus 101A. The information processing apparatus 1B inputs the sensor value acquired from the sensor value conversion model 204 and the target characteristic value of the substrate to be processed to the control input value determination model 202, and acquires the control input value output by the control input value determination model 202. The information processing apparatus 1B inputs the control input value acquired from the control input value determination model 202 to the control input value conversion model 205, and acquires the control input value output by the control input value conversion model 205, that is, the control input value converted into the control input value of the target substrate processing apparatus 101B. The information processing apparatus 1B inputs the control input value acquired from control input value conversion model 205 to the target substrate processing apparatus 101B, thereby causing the target substrate processing apparatus 101B to perform substrate processing corresponding to the target characteristic value.

In this way, the information processing apparatus 1B interposes the sensor value conversion model 204 and the control input value conversion model 205. In this manner, the information processing apparatus 1B can perform monitoring, controlling, or the like on the target substrate processing apparatus 101B by using the characteristic value estimation model 201 and the control input value determination model 202 which are generated for performing monitoring, controlling, or the like on the reference substrate processing apparatus 101A.

### <Flowchart>

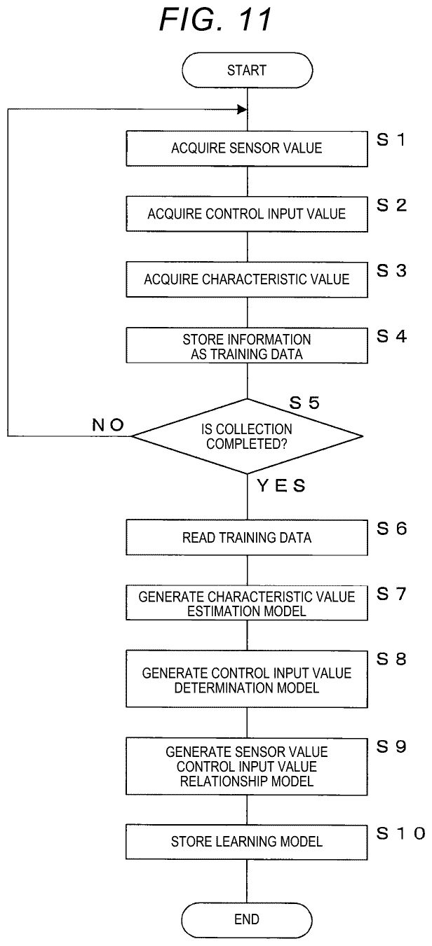

FIG. 11 is a flowchart illustrating an example of a procedure of the learning model generation processing performed by the information processing apparatus 1A according to the present embodiment. The information processing apparatus 1A according to the present embodiment performs predetermined substrate processing, for example, substrate processing such as a trial run in which settings or procedures for data collection are defined, on the reference substrate processing apparatus 101A that has been confirmed to operate normally, and performs data collection for machine learning. The information acquisition unit 11a of the processor 11 of the information processing apparatus 1A communicates with the reference substrate processing apparatus 101A through the communication unit 13, and acquires the sensor value detected by one sensor or a plurality of sensors provided in the reference substrate processing apparatus 101A (Step S1). The information acquisition unit 11a acquires the control input value input to the reference substrate processing apparatus 101A for the sensor value acquired in Step S1 (Step S2). The information acquisition unit 11a acquires characteristic value acquired by measuring the substrate processed by the reference substrate processing apparatus 101A with the characteristic value measurement apparatus 102 by causing the communication unit 13 to communicate with the characteristic value measurement apparatus 102 (Step S3).

The information acquisition unit 11a stores the sensor value acquired in Step S1, the control input value acquired in Step S2, and the characteristic value acquired in Step S3 as the training data in the training data storage 12c in association with each other (Step S4). For example, the information acquisition unit 11a determines whether to complete the collection of the training data, based on whether sufficient data is collected to perform the machine learning (Step S5). When the collection of the training data is not completed (S5: NO), the information acquisition unit 11a returns the processing to Step S1, and continues to collect the training data. When the collection of the training data is completed (S5: YES), the information acquisition unit 11a advances the processing to Step S6.

The model generator 11b of the processor 11 reads the training data stored in the training data storage 12c (Step S6). The model generator 11b performs so-called supervised machine learning processing in which input information (explanatory variable) is set for the sensor value and the control input value which are included in the training data read in Step S6, and output information (response variable, correct value) is set for the corresponding characteristic value. In this manner, the model generator 11b generates the characteristic value estimation model 201 (Step S7). The model generator 11b performs so-called supervised machine learning processing in which input information (explanatory variable) is set for the sensor values and the characteristic value which are included in the training data, and output information (response variable, correct value) is set for the corresponding control input value. In this manner, the model generator 11b generates the control input value determination model 202 (Step S8).

The model generator 11b performs so-called supervised machine learning processing in which output information (response variable, correct value) is set for any one of the plurality of sensor values and control input values which are included in the training data, and input information (explanatory variable) is set for the remaining sensor value and control input value. In this manner, the model generator 11b generates the sensor value control input value relationship model 203 for one sensor value or one control input value set as the output information. The model generator 11b replaces a correspondence between input information and output information to perform similar machine learning processing. In this manner, the model generator 11b generates the sensor value control input value relationship model 203 for each value of the sensor value or the control input value (Step S9)

The model generator 11b causes the model information storage 12b to store information on the characteristic value estimation model 201 generated in Step S7, information on the control input value determination model 202 generated in Step S8, and information on the plurality of sensor value control input value relationship models 203 generated in Step S9, for example, information on the configuration of the learning model and information on the parameters or the like determined through the machine learning (Step S10), and completes the processing.

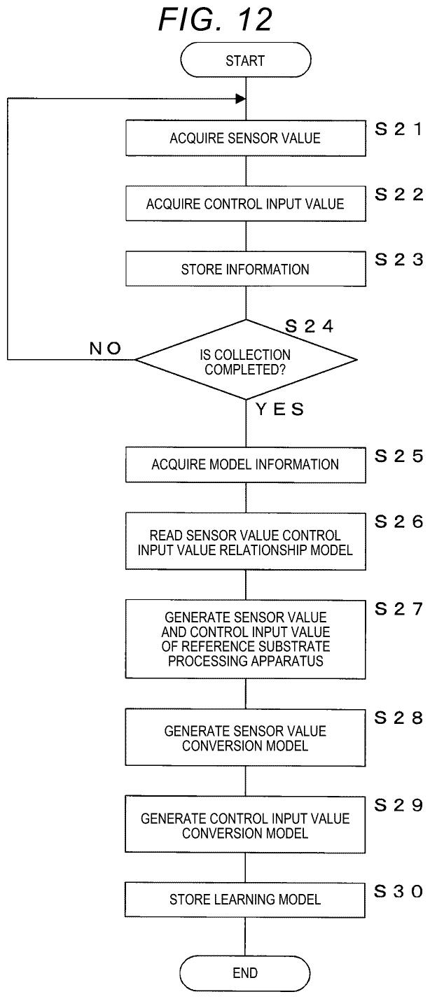

FIG. 12 is a flowchart illustrating an example of a procedure of the learning model generation processing performed by the information processing apparatus 1B according to the present embodiment. For example, the information processing apparatus 1B according to the present embodiment performs predetermined substrate processing, for example, substrate processing such as a trial run in which settings or procedures for data collection are defined, on the target substrate processing apparatus 101B newly introduced into a substrate processing factory, and performs data collection for the machine learning. The information acquisition unit 11a of the processor 11 of the information processing apparatus 1B communicates with the target substrate processing apparatus 101B through the communication unit 13, and acquires the sensor value detected by one sensor or a plurality of sensors provided in the target substrate processing apparatus 101B (Step S21). The information acquisition unit 11a acquires the control input value input to the target substrate processing apparatus 101B for the sensor value acquired in Step S21 (Step S22).

The information acquisition unit 11a stores the sensor value acquired in Step S21 and the control input value acquired in Step S22 as the training data in the training data storage 12c in association with each other (Step S23). For example, the information acquisition unit 11a determines whether to complete the collection of the training data, based on whether sufficient data is collected to perform the machine learning (Step S24). When the collection of the training data is not completed (S24: NO), the information acquisition unit 11a returns the processing to Step S21, and continues to collect training data. When the collection of the training data is completed (S24: YES), the information acquisition unit 11a advances the processing to Step S25.

For example, the model generator 11b of the processor 11 communicates with the information processing apparatus 1A through the communication unit 13 or receives and transmits information via a recording medium, for example. In this manner, the model generator 11b acquires information on the characteristic value estimation model 201, the control input value determination model 202, and the sensor value control input value relationship model 203 which are generated by the information processing apparatus 1A (Step S25), and stores the information in the model information storage 12b. The model generator 11b reads the sensor value control input value relationship model 203 stored in the model information storage 12b (Step S26). The model generator 11b generates the sensor value and the control input value for the reference substrate processing apparatus 101A, based on the sensor value and the control input value of the target substrate processing apparatus 101B which are included in the training data stored in the training data storage 12c, and the sensor value control input value relationship model 203 read in Step S26 (Step S27).

The model generator 11b performs so-called supervised machine learning processing in which input information (explanatory variable) is set for the sensor values of the target substrate processing apparatus 101B which is included in the training data, and output information (response variable, correct value) is set for the sensor value of the reference substrate processing apparatus 101A which is acquired from the sensor value control input value relationship model 203 in Step S27. In this manner, the model generator 11b generates the sensor value conversion model 204 (Step S28). The model generator 11b performs so-called supervised machine learning processing in which input information (explanatory variable) is set for the control input value of the target substrate processing apparatus 101B which is included in the training data, and output information (response variable, correct value) is set for the control input value of the reference substrate processing apparatus 101A which is acquired from the sensor value control input value relationship model 203 in Step S27. In this manner, the model generator 11b generates the control input value conversion model 205 (Step S29).

The model generator 11b causes the model information storage 12b to store information on the sensor value conversion model 204 generated in Step S28 and the control input value conversion model 205 generated in Step S29, for example, information on the configuration of the learning model and information such as the parameters determined through the machine learning, (Step S30), and completes the processing.

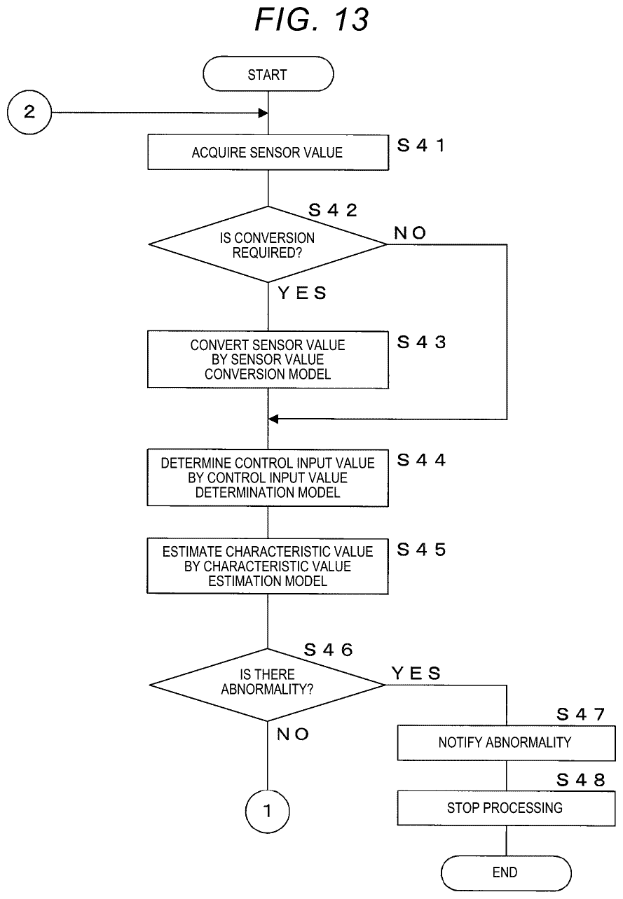

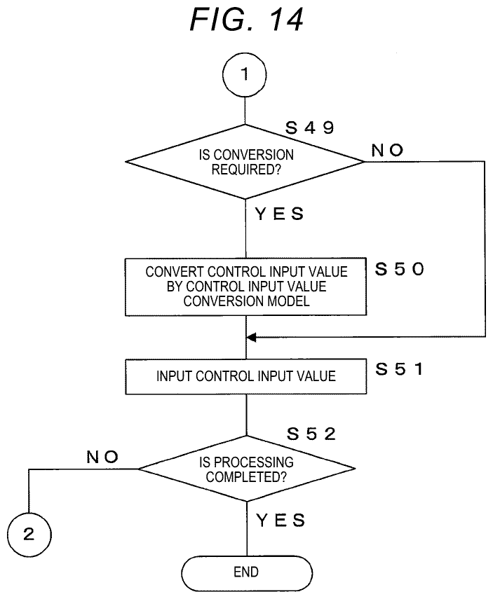

FIGS. 13 and 14 are flowcharts illustrating an example of a procedure of monitoring and control processing of the substrate processing apparatus 101 which are performed by the information processing apparatus 1 according to the present embodiment. The information acquisition unit 11a of the processor 11 of the information processing apparatus 1 according to the present embodiment communicates with the substrate processing apparatus 101 through the communication unit 13, and acquires the sensor value detected by one sensor or a plurality of sensors provided in the substrate processing apparatus 101 (Step S41). The information acquisition unit 11a determines whether it is necessary to convert the sensor value acquired in Step S41 from the sensor value of the target substrate processing apparatus 101B into the sensor value of the reference substrate processing apparatus 101A (Step S42).

For example, in the information processing system according to the present embodiment, setting information indicating whether the information processing apparatus 1 is either the information processing apparatus 1A that performs monitoring, controlling, or the like on the reference substrate processing apparatus 101A or the information processing apparatus 1B that performs monitoring, controlling, or the like on the target substrate processing apparatus 101B is input in advance by the user or the like, and is stored in the storage 12 or the like. The information acquisition unit 11a can determine whether it is necessary to convert the sensor value, by reading the setting information and determining whether the information processing apparatus itself is either the information processing apparatus 1A or the information processing apparatus 1B. When the information acquisition unit 11a determines that the information processing apparatus itself is the information processing apparatus 1B that performs monitoring, controlling, or the like on the target substrate processing apparatus 101B and that it is necessary to convert the sensor value (S42: YES), the information acquisition unit 11a converts the sensor value of the target substrate processing apparatus 101B acquired in Step S41 into the sensor value of the reference substrate processing apparatus 101A by using the sensor value conversion model 204 stored in the model information storage 12b (Step S43), and advances the processing to Step S44. When the information acquisition unit 11a determines that the information processing apparatus itself is the information processing apparatus 1A that performs monitoring, control, and the like on the reference substrate processing apparatus 101A and that it is not necessary to convert the sensor value (S42: NO), the information acquisition unit 11a advances the processing to Step S44.

The control processor 11d of the processor 11 inputs the sensor value acquired in Step S41, or the sensor value converted in Step S43, and the target characteristic value of the substrate processed by the substrate processing apparatus 101 to the control input value determination model 202 stored in model information storage 12b. The control processor 11d acquires the control input value output by the control input value determination model 202, thereby determining the control input value corresponding to the sensor value and the target characteristic value (Step S44). The target characteristic value is input in advance by a user or the like, and is stored as the setting information in the storage 12.

The characteristic value estimation unit 11c of the processor 11 inputs the sensor value acquired in Step S41 or the sensor value converted in Step S43, and the control input value determined in Step S44, to the characteristic value estimation model 201 stored in the model information storage 12b. The characteristic value estimation unit 11c estimates characteristic value of the substrate processed by the substrate processing apparatus 101 by acquiring characteristic value output by the characteristic value estimation model 201 (Step S45). For example, based on the characteristic value estimated in Step S45, the characteristic value estimation unit 11c determines whether the characteristic value exceeds a threshold value or the like, thereby determining the presence or absence of an abnormality relating to the substrate processing performed by the substrate processing apparatus 101, (Step S46). When it is determined that there is the abnormality (S46: YES), for example, the display processor 11 of the processor 11 notifies a user of the abnormality by displaying a message notifying the occurrence of the abnormality on the display unit 14 (Step S47). The control processor 11d stops the substrate processing in which the abnormality occurs (Step S48), and completes the processing.

When it is determined that there is no abnormality, based on the estimated characteristic value (S46: NO), the control processor 11d determines whether it is necessary to convert the control input value determined in Step S44 from the control input value of the reference substrate processing apparatus 101A into the control input value of the target substrate processing apparatus 101B (Step S49). As described above, in the information processing system according to the present embodiment, setting information indicating whether the information processing apparatus 1 is either the information processing apparatus 1A that performs monitoring, controlling, or the like on the reference substrate processing apparatus 101A or the information processing apparatus 1B that performs monitoring, controlling, or the like on the target substrate processing apparatus 101B is stored in the storage 12 or the like. The control processor 11d can determine whether it is necessary to convert the control input value by reading the setting information and determining whether the information processing apparatus itself is either the information processing apparatus 1A or the information processing apparatus 1B.

When the control processor 11d determines that the information processing apparatus itself is the information processing apparatus 1B that performs monitoring, controlling, or the like on the target substrate processing apparatus 101B, and that it is necessary to convert the control input value (S49: YES), the control processor 11d converts the control input value of the reference substrate processing apparatus 101A which is acquired in Step S44 into the control input value of the target substrate processing apparatus 101B, by using the control input value conversion model 205 stored in the model information storage 12b (Step S50), and advances the processing to Step S51. When the control processor 11d determines that the information processing apparatus itself is the information processing apparatus 1A that performs monitoring, control, and the like of the reference substrate processing apparatus 101A, and that it is not necessary to convert the control input value (S49: NO), the control processor 11d advances the processing to Step S51.

The control processor 11d inputs the control input value determined in Step S44 or the control input value converted in Step S50 to the substrate processing apparatus 101 (Step S51). In this manner, the control processor 11d can control the substrate processing performed by the substrate processing apparatus 101. The control processor 11d determines whether the substrate processing is completed by the substrate processing apparatus 101 (Step S52). When the substrate processing is not completed (S52: NO), the control processor 11d returns the processing to Step S41, and repeats the processing described above. When the substrate processing is completed (S52: YES), the control processor 11d completes the processing such as monitoring, controlling, or the like on the substrate processing apparatus 101.

### SUMMARY

In the information processing system according to the present embodiment configured as described above, the information processing apparatus 1 acquires the sensor values of the target substrate processing apparatus 101B. The information processing apparatus 1 inputs the acquired sensor value of the target substrate processing apparatus 101B to the sensor value conversion model 204 subjected to machine learning to receive the sensor value of the target substrate processing apparatus 101B as an input, and to output the sensor value of the reference substrate processing apparatus 101A. The information processing apparatus 1 acquires the sensor value of the reference substrate processing apparatus 101A output from the sensor value conversion model 204. The information processing apparatus 1 inputs the acquired sensor value of the reference substrate processing apparatus 101A together with a desired target characteristic value (target value) to the control input value determination model 202 subjected to machine learning to receive the target characteristic value and the sensor value of the reference substrate processing apparatus 101A as inputs, and to output the control input value of the reference substrate processing apparatus 101A. The information processing apparatus 1 acquires the control input value of the reference substrate processing apparatus 101A which is output by the control input value determination model 202. The information processing apparatus 1 inputs the acquired control input value of the reference substrate processing apparatus 101A to the control input value conversion model 205 subjected to machine learning to receive the control input value of the reference substrate processing apparatus 101A as an input, and to output the control input value of the target substrate processing apparatus 101B. The information processing apparatus 1 acquires the control input value of the target substrate processing apparatus 101B which is output by the control input value conversion model 205. The information processing apparatus 1 controls the target substrate processing apparatus 101B, based on the acquired control input value.

In this manner, in the information processing system according to the present embodiment, the information processing apparatus 1 that controls the target substrate processing apparatus 101B can control the target substrate processing apparatus 101B by using the control input value determination model 202 generated for the reference substrate processing apparatus 101A. Therefore, the information processing system according to the present embodiment can be expected to control the target substrate processing apparatus 101B by correcting an apparatus difference from the reference substrate processing apparatus 101A by using the sensor value conversion model 204 and the control input value conversion model 205.

In the information processing system according to the present embodiment, the information processing apparatus 1 acquires the training data in which the sensor value and the control input value of the target substrate processing apparatus 101B are associated. Based on the sensor value control input value relationship model 203 generated in advance for the reference substrate processing apparatus 101A and the acquired training data, the information processing apparatus 1 acquires the sensor value and the control input value of the reference substrate processing apparatus 101A which correspond to the sensor value and the control input value of the target substrate processing apparatus 101B. The sensor value control input value relationship model 203 is the learning model subjected to machine learning to receive some of the plurality of sensor values and control input values as inputs, and to output the sensor values or the control input values of the reference substrate processing apparatus 101A which are not included in the some of the plurality of sensor values and control input values. The information processing apparatus 1 generates the sensor value conversion model 204 through the machine learning based on the sensor value of the target substrate processing apparatus 101B and the sensor value of the reference substrate processing apparatus 101A. The information processing apparatus 1 generates the control input value conversion model 205 through the machine learning based on the control input value of the target substrate processing apparatus 101B and the control input value of the reference substrate processing apparatus 101A.

In the information processing system according to the present embodiment, the information processing apparatus 1 that performs monitoring, controlling, or the like on the reference substrate processing apparatus 101A acquires the training data in which the sensor value and the control input value of the reference substrate processing apparatus 101A are associated. The information processing apparatus 1 generates the sensor value control input value relationship model 203 through the machine learning using the training data.

In this manner, the information processing system according to the present embodiment, the information processing apparatus 1 performing monitoring, control, and the like on the target substrate processing apparatus 101B can generate and use the sensor value conversion model 204 and the control input value conversion model 205 by using the sensor value control input value relationship model 203 relating to the reference substrate processing apparatus 101A.

In the information processing system according to the present embodiment, the information processing apparatus 1 acquires the training data relating to the reference substrate processing apparatus 101A, in which the sensor value, the control input value, and the characteristic value are associated, and generates the control input value determination model 202 through the machine learning using the training data. The information processing apparatus 1 generates the characteristic value estimation model that receives the sensor value and the control input value of the reference substrate processing apparatus 101A as inputs, and that outputs the characteristic value of the reference substrate processing apparatus 101A, by using the training data. Since the learning models are used, the information processing apparatus 1 can perform monitoring, controlling, or the like on the reference substrate processing apparatus 101A. Since the learning models are combined with the sensor value conversion model 204 and the control input value conversion model 205 which are described above, the information processing apparatus 1 can perform monitoring, controlling, or the like on the target substrate processing apparatus 101B.

In the information processing system according to the present embodiment, the information processing apparatus 1 acquires the sensor value of the target substrate processing apparatus 101B, inputs the acquired sensor value to the sensor value conversion model 204, and acquires sensor value of the reference substrate processing apparatus 101A output by the sensor value conversion model 204. The information processing apparatus 1 inputs the acquired sensor value of the reference substrate processing apparatus 101A together with the desired target characteristic value to the control input value determination model 202, and acquires the control input value of the reference substrate processing apparatus 101A which is output by the control input value determination model 202. The information processing apparatus 1 inputs the sensor value and the control input value of the reference substrate processing apparatus 101A to the characteristic value estimation model 201, and acquires the characteristic value of the reference substrate processing apparatus 101A which is output by the characteristic value estimation model 201. The information processing apparatus 1 outputs information on the acquired characteristic value, for example, a determination result of the presence or absence of the abnormality based on the characteristic value, or the like.

In this manner, in the information processing system according to the present embodiment, the information processing apparatus 1 controlling the target substrate processing apparatus 101B can monitor the presence or absence of the abnormality or the like in the target substrate processing apparatus 101B, by using the characteristic value estimation model 201 generated for the reference substrate processing apparatus 101A. Accordingly, the information processing system according to the present embodiment can be expected to monitor the target substrate processing apparatus 101B by correcting an apparatus difference from the reference substrate processing apparatus 101A by using the sensor value conversion model 204 and the control input value conversion model 205.

### Second Embodiment

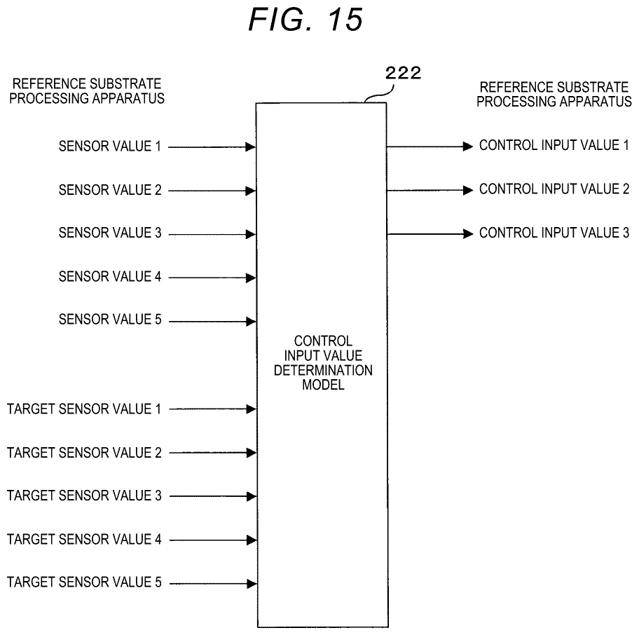

FIG. 15 is a schematic diagram illustrating a configuration example of a control input value determination model 222 according to a second embodiment. The control input value determination model 202 described above has a configuration that receives the sensor values 1 to 5 and the target characteristic value relating to the reference substrate processing apparatus 101A as inputs, and that outputs the control input values 1 to 3 to be input to the reference substrate processing apparatus 101A (refer to FIG. 5). The target value received by the control input value determination model as an input is not limited to the target characteristic value. The control input value determination model 222 according to the second embodiment receives the sensor values 1 to 5 relating to the reference substrate processing apparatus 101A and the target sensor values 1 to 5 which are target values of the sensor values 1 to 5 as inputs, and outputs the control input values 1 to 3 to be input to the reference substrate processing apparatus 101A.

The information processing apparatus 1 according to the second embodiment includes the control input value determination model 222 having a configuration illustrated in FIG. 15, instead of the control input value determination model 202 or in addition to the control input value determination model 202. The information processing apparatus 1A according to the second embodiment can perform substrate processing such that the sensor value output by the reference substrate processing apparatus 101A becomes the target sensor value, by performing feedback control using the control input value determination model 222.

For example, the control input value determination model 222 according to the second embodiment is generated by the information processing apparatus 1A that performs monitoring, controlling, or the like on the reference substrate processing apparatus 101A. For example, the information processing apparatus 1A performs substrate processing in the reference substrate processing apparatus 101A, and causes the training data storage 12c to store and accumulate the training data in which the target sensor value at this time, the control input value input to the reference substrate processing apparatus 101A, and the sensor value acquired from the sensor in the reference substrate processing apparatus 101A are associated. The information processing apparatus 1A can generate the control input value determination model 222 by performing so-called supervised machine learning processing in which input information (explanatory variable) is set for the sensor value and the target sensor value which are included in the training data, and output information (response variable, correct value) is set for the control input value.

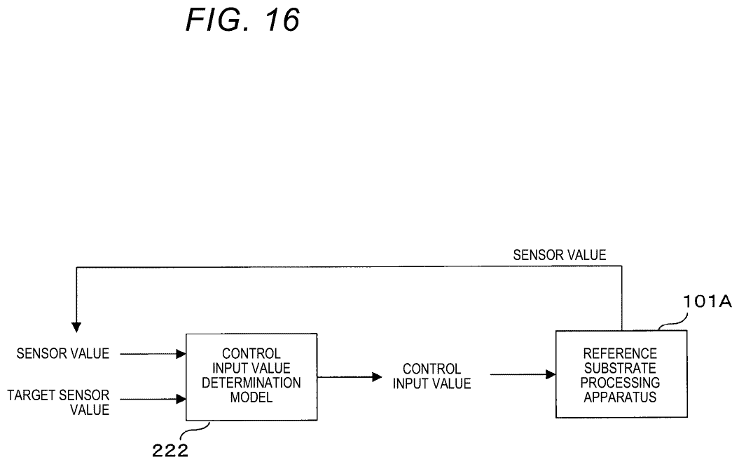

FIG. 16 is a schematic diagram for describing the control of the reference substrate processing apparatus 101A which is performed by the information processing apparatus 1A. The information processing apparatus 1A inputs the sensor value acquired from the reference substrate processing apparatus 101A and the target sensor value that becomes the target value of the sensor to the control input value determination model 222, and acquires the control input value output by the control input value determination model 222. The information processing apparatus 1A inputs the control input value acquired from the control input value determination model 222 to the reference substrate processing apparatus 101A, thereby causing the reference substrate processing apparatus 101A to perform substrate processing corresponding to the target sensor value, and acquiring the sensor value of the reference substrate processing apparatus 101A at this time.

The information processing apparatus 1A feeds back the acquired sensor value, and inputs the value to the control input value determination model 222. At this time, the information processing apparatus 1A inputs the target sensor value the same as before to the control input value determination model 222. The information processing apparatus 1A acquires the control input value output by the control input value determination model 222, inputs the control input value to the reference substrate processing apparatus 101A, and acquires the sensor value output by the reference substrate processing apparatus 101A. Since the information processing apparatus 1A repeats this processing cycle, the sensor value output by the reference substrate processing apparatus 101A can be close to the target sensor value.

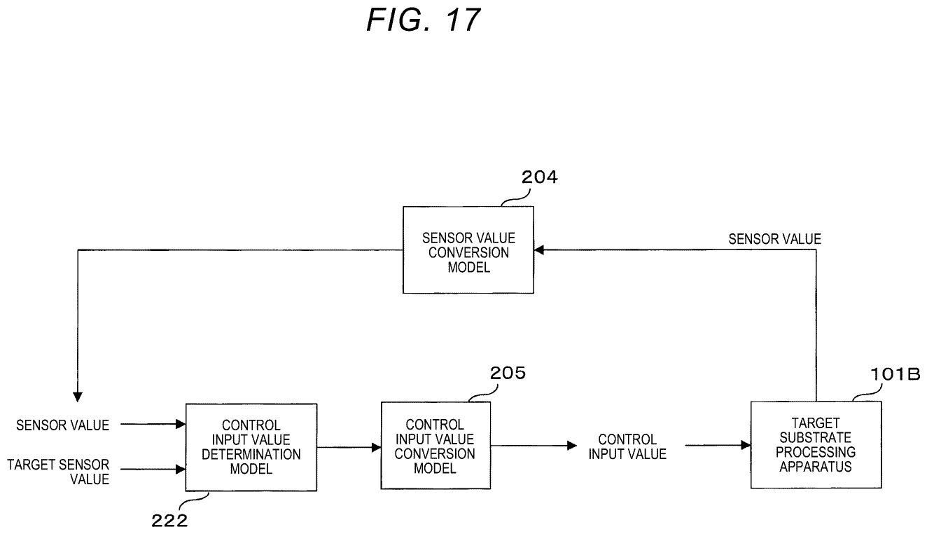

FIG. 17 is a schematic diagram for describing the control of the target substrate processing apparatus 101B which is performed by the information processing apparatus 1B. The information processing apparatus 1B inputs the sensor value acquired from the target substrate processing apparatus 101B to the sensor value conversion model 204, and acquires the sensor value of the reference substrate processing apparatus 101A which is output by the sensor value conversion model 204. The information processing apparatus 1B inputs the sensor value of the reference substrate processing apparatus 101A acquired from the sensor value conversion model 204 and the target sensor value that becomes the target value of the sensor to the control input value determination model 222, and acquires the control input value for the reference substrate processing apparatus 101A output by the control input value determination model 222. The information processing apparatus 1B inputs the acquired control input value of the reference substrate processing apparatus 101A to the control input value conversion model 205, and acquires the control input value for the target substrate processing apparatus 101B which is output by the control input value conversion model 205. The information processing apparatus 1B inputs the control input value acquired from the control input value conversion model 205 to the target substrate processing apparatus 101B, thereby causing the target substrate processing apparatus 101B to perform substrate processing corresponding to the target sensor value, and acquiring the sensor value of the target substrate processing apparatus 101B at this time.

Since the information processing apparatus 1B repeats this processing cycle, the sensor value output by the target substrate processing apparatus 101B can be close to the target sensor value. Since the sensor value conversion model 204 and the control input value conversion model 205 are used, the information processing apparatus 1B can control the target substrate processing apparatus 101B by using the control input value determination model 222 generated for controlling the reference substrate processing apparatus 101A.

Since the other configurations of the information processing system according to the second embodiment are the same as those of the information processing system according to the first embodiment, the same reference numerals are given to the same locations, and a detailed description thereof will be omitted.

The embodiments disclosed herein are exemplary in all respects and can be considered to be not restrictive. The scope of the present disclosure is indicated by the claims, not the above-described meaning, and is intended to include all modifications within the meaning and scope equivalent to the claims.

The features described in each embodiment can be combined with each other. In addition, the independent and dependent claims set forth in the claims can be combined with each other in any and all combinations, regardless of the reciting format. Furthermore, the claims use a format of describing claims that recite two or more other claims (multi-claim format). However, the present disclosure is not limited thereto. The claims may also be described using a format of multi-claims reciting at least one multi-claim (multi-multi claims).

The invention claimed is:

1. An information processing method causing an information processing apparatus to execute a process comprising:
acquiring a sensor value of a target apparatus;
inputting the acquired sensor value of the target apparatus to a sensor value conversion model subjected to machine learning to receive the sensor value of the target apparatus as an input, and to output a sensor value of a reference apparatus, and acquiring the sensor value of the reference apparatus which is output by the sensor value conversion model;
inputting the acquired sensor value of the reference apparatus together with a desired target value to a control input value determination model subjected to machine learning to receive the target value and the sensor value of the reference apparatus as inputs, and to output a control input value of the reference apparatus, and acquiring the control input value of the reference apparatus which is output by the control input value determination model;
inputting the acquired control input value of the reference apparatus to a control input value conversion model subjected to machine learning to receive the control input value of the reference apparatus as an input, and to output a control input value of the target apparatus, and acquiring the control input value of the target apparatus which is output by the control input value conversion model; and
controlling the target apparatus, based on the acquired control input value of the target apparatus.

2. The information processing method according to claim 1, wherein the process further includes:
acquiring training data in which the sensor value and the control input value for the target apparatus are associated;
acquiring the sensor value and the control input value of the reference apparatus which correspond to the sensor value and the control input value of the target apparatus which are included in the training data, based on a sensor value control input value relationship model subjected to machine learning to receive some of a plurality of the sensor values and control input values as inputs, and to output the sensor value or the control input value of the reference apparatus which is not included in the some of the plurality of sensor values and control input values, and the acquired training data,
generating the sensor value conversion model by using machine learning based on the sensor value included in the training data and the acquired sensor value of the reference apparatus; and
generating the control input value conversion model by using machine learning based on the control input value included in the training data and the acquired control input value of the reference apparatus.

3. The information processing method according to claim 2, wherein the process further includes:
acquiring training data in which the sensor value and the control input value for the reference apparatus are associated; and
generating the sensor value control input value relationship model by using machine learning using the acquired training data.

4. The information processing method according to claim 1, wherein the process further includes:
acquiring training data associated with the sensor value, the control input value, and a characteristic value of the reference apparatus; and
generating the control input value determination model, based on the acquired training data.

5. The information processing method according to claim 4, wherein the process further includes:
generating a characteristic value estimation model that receives the sensor value and the control input value of the reference apparatus as inputs, and that outputs the characteristic value of the reference apparatus, based on the acquired training data.

6. The information processing method according to claim 5, wherein the process further includes:
inputting the acquired sensor value and the acquired control input value of the reference apparatus to the characteristic value estimation model, and acquiring the characteristic value of the reference apparatus which is output by the characteristic value estimation model, and
outputting information on the acquired characteristic value.

7. The information processing method according to claim 6, wherein the process further includes:
determining presence or absence of an abnormality, based on the acquired characteristic value;
outputting determined information on the presence or absence of the abnormality;
stopping substrate processing in response to determine the presence or absence of the abnormality; and
completing the substrate processing.

8. An information processing method causing an information processing apparatus to execute a process comprising:
acquiring a sensor value of a target apparatus;
inputting the acquired sensor value of the target apparatus to a sensor value conversion model subjected to machine learning to receive the sensor value of the target apparatus as an input, and to output a sensor value of a reference apparatus, and acquiring the sensor value of the reference apparatus which is output by the sensor value conversion model;
inputting the acquired sensor value of the reference apparatus together with a desired target value to a control input value determination model subjected to machine learning to receive the target value and the sensor value of the reference apparatus as inputs, and to output a control input value of the reference apparatus, and acquiring the control input value of the reference apparatus which is output by the control input value determination model;
inputting the acquired sensor value and the acquired control input value of the reference apparatus to a characteristic value estimation model subjected to machine learning to receive the sensor value and the control input value of the reference apparatus as inputs, and to output a characteristic value of the reference apparatus, and acquiring the characteristic value of the reference apparatus which is output by the characteristic value estimation model;
outputting information on the acquired characteristic value of the reference apparatus; and
controlling the target apparatus based on the acquired characteristic value of the reference apparatus.

9. A non-transitory computer readable medium storing a program that causes a computer to execute a process comprising:
acquiring a sensor value of a target apparatus;
inputting the acquired sensor value of the target apparatus to a sensor value conversion model subjected to machine learning to receive the sensor value of the target apparatus as an input, and to output a sensor value of a reference apparatus, and acquiring the sensor value of the reference apparatus which is output by the sensor value conversion model;
inputting the acquired sensor value of the reference apparatus together with a desired target value to a control input value determination model subjected to machine learning to receive the target value and the sensor value of the reference apparatus as inputs, and to output a control input value of the reference apparatus, and acquiring the control input value of the reference apparatus which is output by the control input value determination model;
inputting the acquired control input value of the reference apparatus to a control input value conversion model subjected to machine learning to receive the control input value of the reference apparatus as an input, and to output a control input value of the target apparatus, and acquiring the control input value of the target apparatus which is output by the control input value conversion model; and
controlling the target apparatus, based on the acquired control input value of the target apparatus.

10. A non-transitory computer readable medium storing a program that causes a computer to execute a process comprising:
acquiring a sensor value of a target apparatus;
inputting the acquired sensor value of the target apparatus to a sensor value conversion model subjected to machine learning to receive the sensor value of the target apparatus as an input, and to output a sensor value of a reference apparatus, and acquiring the sensor value of the reference apparatus which is output by the sensor value conversion model;
inputting the acquired sensor value of the reference apparatus together with a desired target value to a control input value determination model subjected to machine learning to receive the target value and the sensor value of the reference apparatus as inputs, and to output a control input value of the reference apparatus, and acquiring the control input value of the reference apparatus which is output by the control input value determination model;
inputting the acquired sensor value and the acquired control input value of the reference apparatus to a characteristic value estimation model subjected to machine learning to receive the sensor value and the control input value of the reference apparatus as inputs, and to output a characteristic value of the reference apparatus, and acquiring the characteristic value of the reference apparatus which is output by the characteristic value estimation model;
outputting information on the acquired characteristic value of the reference apparatus; and
controlling the target apparatus based on the acquired characteristic value of the reference apparatus.

11. An information processing apparatus comprising:
circuitry configured to:
acquire a sensor value of a target apparatus,
input the acquired sensor value of the target apparatus to a sensor value conversion model subjected to machine learning to receive the sensor value of the target apparatus as an input, and to output a sensor value of a reference apparatus, and acquire the sensor value of the reference apparatus which is output by the sensor value conversion model,
input the acquired sensor value of the reference apparatus together with a desired target value to a control input value determination model subjected to machine learning to receive the target value and the sensor value of the reference apparatus as inputs, and to output a control input value of the reference apparatus, and acquire the control input value of the reference apparatus which is output by the control input value determination model,
input the acquired control input value of the reference apparatus to a control input value conversion model subjected to machine learning to receive the control input value of the reference apparatus as an input, and to output a control input value of the target apparatus, and acquire the control input value of the target apparatus which is output by the control input value conversion model; and
control the target apparatus, based on the acquired control input value of the target apparatus.

12. An information processing apparatus comprising:
circuitry configured to:
acquire a sensor value of a target apparatus,
input the acquired sensor value of the target apparatus to a sensor value conversion model subjected to machine learning to receive the sensor value of the target apparatus as an input, and to output a sensor value of a reference apparatus, and acquire the sensor value of the reference apparatus which is output by the sensor value conversion model;
input the acquired sensor value of the reference apparatus together with a desired target value to a control input value determination model subjected to machine learning to receive the target value and the sensor value of the reference apparatus as inputs, and to output a control input value of the reference apparatus, and acquire the control input value of the reference apparatus which is output by the control input value determination model;
input the acquired sensor value and the acquired control input value of the reference apparatus to a characteristic value estimation model subjected to machine learning to receive the sensor value and the control input value of the reference apparatus as inputs, and to output a characteristic value of the reference apparatus, and acquire the characteristic value of the reference apparatus which is output by the characteristic value estimation model;
output information on the acquired characteristic value of the reference apparatus; and
control the target apparatus, based on the acquired control input value of the target apparatus.

13. The non-transitory computer readable medium according to claim 9, wherein the process further includes:
acquiring training data in which the sensor value and the control input value for the target apparatus are associated;
acquiring the sensor value and the control input value of the reference apparatus which correspond to the sensor value and the control input value of the target apparatus which are included in the training data, based on a sensor value control input value relationship model subjected to machine learning to receive some of a plurality of the sensor values and control input values as inputs, and to output the sensor value or the control input value of the reference apparatus which is not included in the some of the plurality of sensor values and control input values, and the acquired training data,
generating the sensor value conversion model by using machine learning based on the sensor value included in the training data and the acquired sensor value of the reference apparatus; and
generating the control input value conversion model by using machine learning based on the control input value included in the training data and the acquired control input value of the reference apparatus.

14. The non-transitory computer readable medium according to claim 13, wherein the process further includes:
acquiring training data in which the sensor value and the control input value for the reference apparatus are associated; and
generating the sensor value control input value relationship model by using machine learning using the acquired training data.

15. The non-transitory computer readable medium according to claim 9, wherein the process further includes:
acquiring training data associated with the sensor value, the control input value, and a characteristic value of the reference apparatus; and
generating the control input value determination model, based on the acquired training data.

16. The non-transitory computer readable medium according to claim 15, wherein the process further includes:
generating a characteristic value estimation model that receives the sensor value and the control input value of the reference apparatus as inputs, and that outputs the characteristic value of the reference apparatus, based on the acquired training data.

17. The non-transitory computer readable medium according to claim 16, wherein the process further includes:
inputting the acquired sensor value and the acquired control input value of the reference apparatus to the characteristic value estimation model, and acquiring the characteristic value of the reference apparatus which is output by the characteristic value estimation model, and
outputting information on the acquired characteristic value.

18. The non-transitory computer readable medium according to claim 17, wherein the process further includes:
determining presence or absence of an abnormality, based on the acquired characteristic value;
outputting determined information on the presence or absence of the abnormality;
stopping substrate processing in response to determine the presence or absence of the abnormality; and
completing the substrate processing.

19. The information processing method according to claim 1, wherein the target apparatus is a substrate processing apparatus, and
the controlling the target apparatus, based on the acquired control input value of the target apparatus, includes performing substrate processing based the acquired control input value of the target apparatus.

20. The information processing method according to claim 19, wherein the control input value of the target apparatus includes controlling a driving amount of an actuator of the target apparatus or controlling a voltage value applied by the target apparatus.
